(19) United States
(12) Patent Application Publication
(10) Pub. No.: US 2025/0006579 A1
(43) Pub. Date: Jan. 2, 2025

(54) MITIGATION OF THRESHOLD VOLTAGE SHIFT IN BACKSIDE POWER DELIVERY USING BACKSIDE PASSIVATION LAYER

(71) Applicant: Intel Corporation, SAnta Clara, CA (US)

(72) Inventors: Avijit Barik, Portland, OR (US); Tao Chu, Portland, OR (US); Minwoo Jang, Portland, OR (US); Aurelia Wang, Hillsboro, OR (US); Conor P. Puls, Portland, OR (US)

(73) Assignee: Intel Corporation, Santa Clara, CA (US)

(21) Appl. No.: 18/216,476

(22) Filed: Jun. 29, 2023

(51) Int. Cl. H01L 23/31; H01L 21/02; H01L 21/8234; H01L 27/02; H01L 27/088; H01L 29/06; H01L 29/417

(52) U.S. Cl. CPC H01L 23/3171; H01L 21/02532; H01L 21/823437; H01L 21/823475; H01L 27/0207; H01L 27/0886; H01L 29/0657; H01L 29/41791

(57) ABSTRACT

Devices, transistor structures, systems, and techniques are described herein related to providing a backside passivation layer on a transistor semiconductor material. The semiconductor material is between source and drain structures, and a gate structure is adjacent a channel region of the semiconductor material. The passivation layer is formed as a conformal insulative layer on a backside of the semiconductor material and is then treated using an ozone/UV cure to remove trap charges from the semiconductor material.

### BACKGROUND

Higher performance, lower cost, increased miniaturization, and greater density of integrated circuits (ICs) are ongoing goals of the electronics industry. Backside interconnects are an important aspect for advancement in the semiconductor industry towards these goals. Backside interconnects, for example, can provide power from the backside of the transistor device. This offers advantages including a lower resistance path to power the transistor devices, opening space on the frontside of the transistor device layout, and others. This, in turn, improves transistor device performance metrics both in per power terms and per area terms.

However, difficulties persist in the deployment of backside power delivery such as introduction of threshold voltage (Vt) shift when exposing the transistors from the backside. The techniques and structures discussed herein offer backside metallization and power delivery with reduced (e.g., zero or close to zero) Vt shift. Such improvements may become critical as the desire to deploy advanced transistor structures becomes even more widespread.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is a flow diagram illustrating methods for mitigating or eliminating threshold voltage shift due to backside semiconductor material etch using a passivation layer;

FIGS. 2A, 3, 4, 5, 6, 7, 8, and 9A are cross-sectional views of transistor structures evolving as the methods of FIG. 1 are practiced to form a backside passivation layer on a transistor semiconductor structure;

FIGS. 2B and 9B are cross-sectional top-down or plan views of the transistor structures of FIGS. 2A and 9A;

FIG. 10 illustrates a cross-sectional side view of an integrated circuit device structure similar to the transistor structure of FIGS. 9A and 9B after incorporation into an integrated circuit die;

FIG. 11 illustrates exemplary systems employing transistor structures having a field effect transistor with a backside passivation layer; and

FIG. 12 is a functional block diagram of an electronic computing device, all in accordance with some embodiments.

### DETAILED DESCRIPTION

One or more embodiments or implementations are now described with reference to the enclosed figures. While specific configurations and arrangements are discussed, it should be understood that this is done for illustrative purposes only. Persons skilled in the relevant art will recognize that other configurations and arrangements may be employed without departing from the spirit and scope of the description. It will be apparent to those skilled in the relevant art that techniques and/or arrangements described herein may also be employed in a variety of other systems and applications other than what is described herein.

Reference is made in the following detailed description to the accompanying drawings, which form a part hereof, wherein like numerals may designate like parts throughout to indicate corresponding or analogous elements. It will be appreciated that for simplicity and/or clarity of illustration, elements illustrated in the figures have not necessarily been drawn to scale. For example, the dimensions of some of the elements may be exaggerated relative to other elements for clarity. Further, it is to be understood that other embodiments may be utilized, and structural and/or logical changes may be made without departing from the scope of claimed subject matter. It should also be noted that directions and references, for example, up, down, top, bottom, over, under, and so on, may be used to facilitate the discussion of the drawings and embodiments and are not intended to restrict the application of claimed subject matter. Therefore, the following detailed description is not to be taken in a limiting sense and the scope of claimed subject matter defined by the appended claims and their equivalents.

In the following description, numerous details are set forth. However, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” or “one embodiment” means that a particular feature, structure, function, or characteristic described in connection with the embodiment is included in at least one embodiment of the invention. Thus, the appearances of the phrase “in an embodiment” or “in one embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. Herein, the term “predominantly” indicates not less than 50% of a particular material or component while the term “substantially pure” indicates not less than 99% of the particular material or component and the term “pure” indicates not less than 99.9% of the particular material or component. Unless otherwise indicated, such material percentages are based on atomic percentage. Herein the term concentration is used interchangeably with material percentage and also indicates atomic percentage unless otherwise indicated.

The terms “coupled” and “connected,” along with their derivatives, may be used herein to describe structural relationships between components. It should be understood that these terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship, an electrical relationship, a functional relationship, etc.).

The terms “over,” “under,” “between,” “on”, and/or the like, as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features. The term immediately adjacent indicates such features are in direct contact. Furthermore, the terms “substantially,” “close,” “approximately,” “near,” and “about,” generally refer to being within +/−10% of a target value. The term layer as used herein may include a single material or multiple materials. As used in throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C. The terms “lateral”, “laterally adjacent” and similar terms indicate two or more components are aligned along a plane orthogonal to a vertical direction of an overall structure. As used herein, the terms “monolithic”, “monolithically integrated”, and similar terms indicate the components of the monolithic overall structure form an indivisible whole not reasonably capable of being separated.

Devices, transistor structures, integrated circuit dies, apparatuses, systems, and techniques are described herein related to a passivation layer applied to the backside a transistor semiconductor material when the transistor semiconductor material is exposed for the deployment of backside power delivery. For example, the present disclosure provides for mitigation of threshold voltage shift in architectures deploying backside power delivery.

As discussed, backside interconnects or backside metallization layers are an important aspect for advancement in the semiconductor industry. Such backside interconnects are vertically opposite from frontside metallization layers with respect to a device layer therebetween. For example, the frontside metallization layers are over a device layer including transistors and the backside metallization layers are under the transistors. During frontside processing (e.g., prior to frontside metallization), a bridge via is fabricated such that the bridge via extends vertically across the device layer. After fabrication of frontside metallization layers (which may contact the bridge via), the backside metallization layers may be formed by attaching a wafer to a carrier, removing the substrate over which the transistors and frontside metallization layers were formed, forming the backside metallization layers, and removing the carrier. Furthermore, as discussed herein, such backside processing may include etching the transistor semiconductor material of the device layer. Notably, such etching and exposure of the transistor semiconductor material introduces trap chares to the transistor semiconductor material of the field effect (FE) transistors. For example, the backside power delivery process may introduce additional trap charges to FE transistors that cause larges inline to end-of-line threshold voltage (Vt) shifts, which is undesirable in Vt targeting. Furthermore, these trap charges may have local layout dependence and cause problem to Vt centering for all transistors. It is desirable to reduce (e.g., have zero or close to zero) inline to end-of-line threshold voltage Vt shift.

As discussed herein, a passivation layer is introduced after backside etch, which exposes the backside of the FE transistor semiconductor material. The passivation layer may any thickness and/or material discussed herein such as a 5 nm SiN (silicon nitride) passivation layer (e.g., a layer including silicon and nitrogen). Following application of the passivation layer, an ozone/ultraviolet light (e.g., O₃/UV) anneal is performed. The passivation layer and ozone/UV anneal or treatment removes trap charges from the previously exposed transistor semiconductor material to the passivation layer for reduced trap charges and mitigation or elimination of the discussed Vt shift. After ozone/UV anneal or treatment, a second insulative layer is formed on the passivation layer (or conformal insulative layer), and planarization is performed to planarize the second insulative layer and expose the discussed bridge via from the backside. For example, the second insulative layer (or insulative fill layer) may be a silicon oxide insulative fill layer (e.g., a layer including silicon and oxygen). The discussed passivation layer and ozone/UV anneal or treatment mitigates or eliminates Vt shift. For example, Vt shift may be reduced by about 15 to 20 mV. The Vt shift may be reduced by a greater amount on devices with a large susceptibility to inline to end-of-line threshold voltage Vt shift.

The discussed backside metallization layers and frontside metallization layers may be interconnected by metal vias that vertically extend across or span the transistors of the device layer. The metal vias may be characterized as vias, deep vias, bridge vis, across-transistor vias, interconnect vias, or the like. In some contexts, the vias may be characterized as power vias as the deliver power from the backside metallization layers to the transistor devices. However, the metal vias may deliver signal routing, ground routing, or provide any suitable interconnection. Notably, the vias bridge the frontside and the backside metallization layers interconnects.

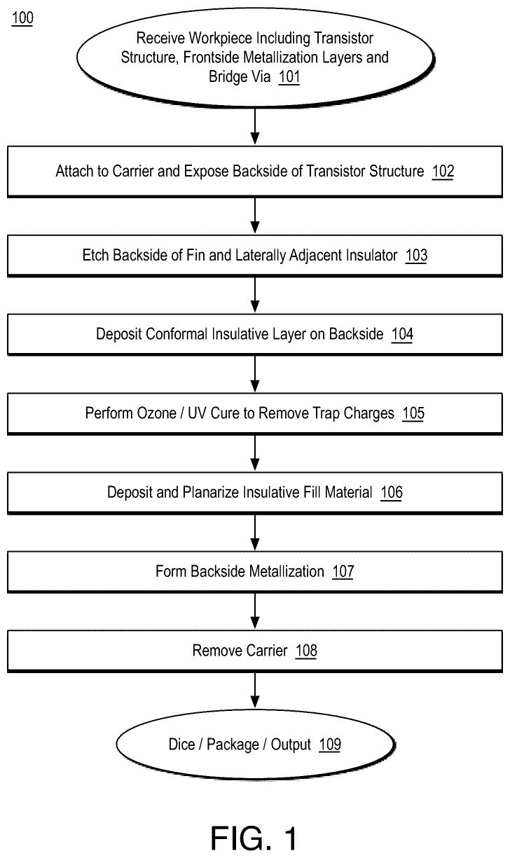

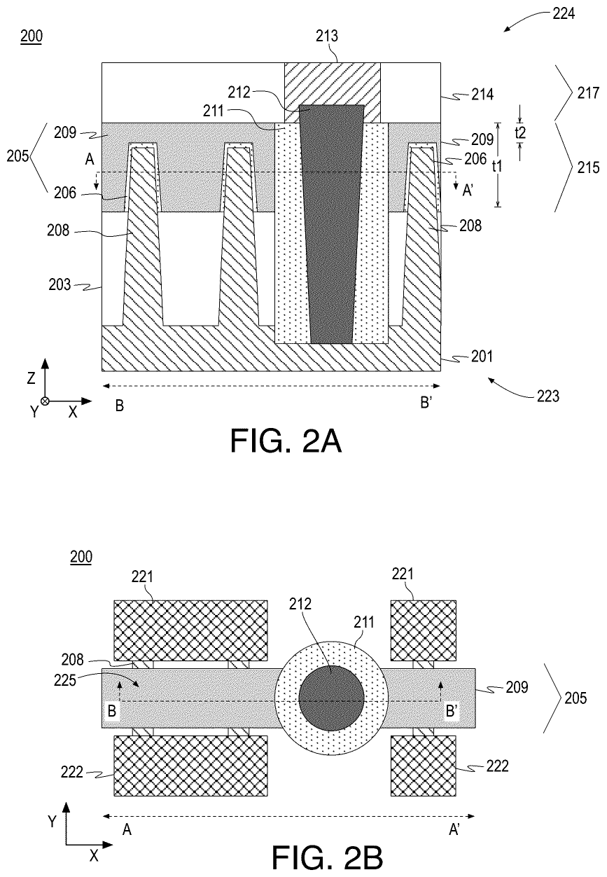

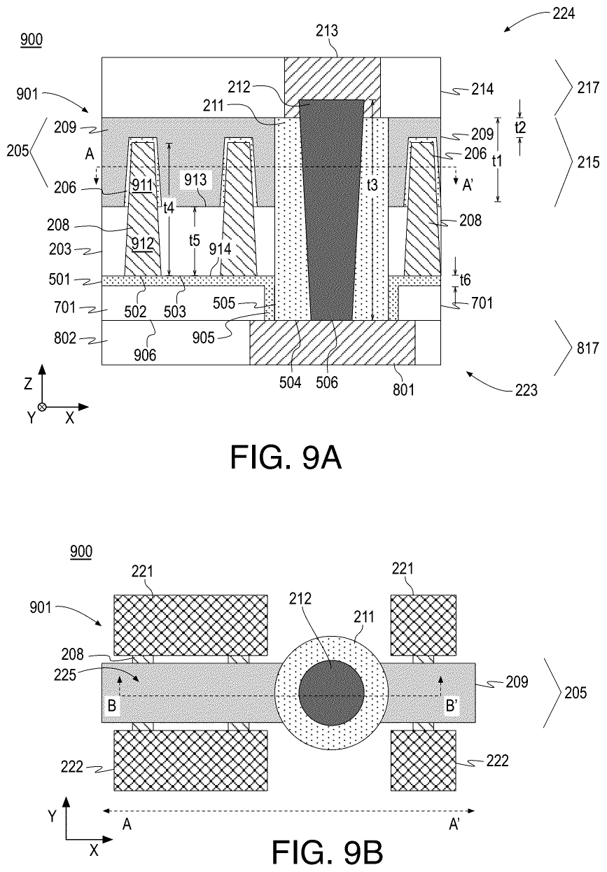

FIG. 1 is a flow diagram illustrating methods 100 for mitigating or eliminating threshold voltage shift due to backside semiconductor material etch using a passivation layer, arranged in accordance with at least some implementations of the present disclosure. FIGS. 2A, 3, 4, 5, 6, 7, 8, and 9A are cross-sectional views of transistor structures evolving as methods 100 are practiced to form a backside passivation layer on a transistor semiconductor structure, arranged in accordance with some embodiments of the disclosure. FIGS. 2B and 9B are cross-sectional top-down or plan views of the transistor structures of FIGS. 2A and 9A, arranged in accordance with some embodiments of the disclosure. As discussed herein, the passivation layer or insulative layer is formed on a backside of an exposed transistor semiconductor structure and an ozone/UV cure is performed to remove trapped charges from the transistor semiconductor structure to mitigate or eliminate threshold voltage shift. Although illustrated with respect to formation of bridge vias within gate tracks of the transistor structures, the bridge vias may be formed at any suitable location such as within and source/drain contact tracks of the transistor structure.

Methods 100 begin at input operation 101, where a workpiece including at least a partially formed transistor structure is received for processing. For example, a substrate may be received for processing such that a transistor or transistor structure has been fabricated over the substrate. In some embodiments, the transistor or transistor structure includes semiconductor structure extending between a source structure and a drain structure. A gate structure (e.g., a gate dielectric and a gate electrode) is between the source and drain structures such that the gate structure is adjacent to a channel region of the one or more semiconductor structures. Furthermore, the source structure and the drain structure may be contacted by source and drain contacts, respectively. For example, the transistor may be part of a transistor layer or device layer formed over the substrate.

Any number of metallization layers may be formed over the frontside transistors of the device layer to interconnect the transistors, provide signal routing, and so on. As used herein the term frontside of a transistor structure indicates the side (or the direction of the side) being built up during front end of line (FEOL) processing of a transistor structure, typically over a wafer substrate, in accordance with the accepted use of frontside. The backside is then opposite the frontside and is the side opposite the buildup direction (e.g., a negative z-direction). The received workpiece may further include a bridge via in contact with the frontside metallization and extending vertically across the transistors of the device layer to extend below the transistors of the device layer. The bridge via may then be contacted from the backside during backside exposure as discussed herein below.

FIG. 2A illustrates a cross-sectional side view of a transistor structure 200 including a metal via 212 extending across a device layer 215 to extend below device layer 215. As shown, transistor structure 200 includes a number of semiconductor structures 208 that include a semiconductor material. Each or several of semiconductor structures 208 correspond to a functional transistor that may be implemented in an integrated circuit. Semiconductor structures 208 may also be characterized as fins. In the context of FIG. 2A, the cross-sectional side view is taken at a gate cut as shown with respect to FIG. 2B.

FIG. 2B provides a top-down or plan view of transistor structure 200, which illustrates that semiconductor structures 208 extend between and contact source structures 221 and drain structures 222. Furthermore, a gate structure 205 is between source structures 221 and drain structures 222 and is adjacent channel regions 225 (obscured in FIG. 2B) of semiconductor structures 208.

With continued reference to FIGS. 2A and 2B, transistor structure 200 may include and be formed over a substrate 201. In some embodiments, as shown, semiconductor structures 208 may be continuous with substrate 201. However, semiconductor structures 208 may also be formed over but discontinuous with substrate 201. Substrate 201 may include any suitable material or materials. For example, substrate 201 may be a substrate substantially aligned along a predetermined crystal orientation (e.g., <100>, <111>, <110>, or the like). In some embodiments, substrate 201 is a semiconductor material such as monocrystalline silicon (Si), germanium (Ge), silicon germanium (SiGe), III-V materials (e.g., gallium arsenide (GaAs)), a silicon carbide (SiC), a sapphire (Al₂O₃), or any combination thereof. In some embodiments, substrate 201 is silicon having a <111> crystal orientation. Semiconductor structures 208 may be any suitable semiconductor material or materials such as silicon, germanium, silicon germanium, a III-V material, any material discussed with respect to substrate 201, or others. In some embodiments, semiconductor structures 208 are formed as fins from substrate 201. In some embodiments, a portion of semiconductor structures 208 (e.g., a subfin) is buried in an insulative material or insulative layer 203. In some embodiments, insulative layer 203 is a silicon oxide (e.g., a layer including silicon and oxygen). However other insulative materials may be used. As used herein the term insulative material indicates a material in which electric current does not flow freely.

As shown, channel region 225 of each of semiconductor structures 208 is surrounded by gate structure 205. Gate structure 205 includes, for example, a gate dielectric 206 on at least a portion of each of semiconductor structures 208 and a gate electrode 209 on gate dielectric 206. As used herein, the term channel region indicates a region or portion of a material or structure that is manipulated by a gate to operate a transistor. Notably, the transistor need not be in operation for a region to be a channel region. Gate dielectric 206 may be silicon oxide, aluminum oxide, or a high-k dielectric, such as hafnium oxide. For example, gate dielectric 206 may include elements such as hafnium, silicon, oxygen, titanium, tantalum, lanthanum, aluminum, zirconium, barium, strontium, yttrium, lead, scandium, niobium, or zinc.

As shown, a gate structure includes gate dielectric 206 and gate electrode 209. Gate electrodes 209 may include any suitable work function metal for transistor gate control such as tantalum, titanium, aluminum, ruthenium, or alloys of such materials and a fill metal such as tungsten. As shown, semiconductor structures 208 extend between a source structure 221 (or source) and a drain structure 222 (or drain). Gate dielectric 206 and gate electrode 209 of gate structure 205 are adjacent channel regions 225 of semiconductor structures 208 to form a three-terminal transistor device. Although illustrated herein with respect to FinFET transistor architectures, the structures and techniques may be deployed with respect to any suitable FET transistor architectures such as tri- or dual-gate transistor architectures, or planar transistor architectures.

As shown, in some embodiments, gate electrode 209 has a depth, vertical height, or thickness t1 (e.g., in the z-direction) that may be in the range of about 50 to 90 nm. In some embodiments, thickness t1 is in the range of 60 to 80 nm. In some embodiments, thickness t1 is in the range of 50 to 60 nm. Other thicknesses may be used. Furthermore, gate electrode may extend a depth, vertical height, or thickness t2 (e.g., in the z-direction) of about 10 to 30 nm over a top surface or top point of semiconductor structures 208. In some embodiments, thickness t2 is in the range of 15 to 25 nm. In some embodiments, thickness t2 is in the range of 10 to 15 nm. Other thicknesses may be used.

Transistor structure 200 further includes metal via 212 formed within an insulative liner layer 211. Metal via 212 contacts a metallization feature 213 of a metallization layer 217 such that metallization feature 213 is embedded in an insulative material 214. Metallization layer 217 may be one of any number of metallization layers such as seven to ten such layers that include metal lines and metal vias interconnecting the metal lines. As shown, metal via 212 (e.g., a bridge via) contacts metallization feature 213 and extends from metallization layer 217 over transistors of device layer 215 to below transistors of device layer 215. That is metal via 212 bridges between a frontside 224 of transistor structure 200 and a backside 223 of transistor structure 200. As discussed, the term frontside of a transistor structure indicates the side (or the direction of the side) being built up during FEOL processing of transistor structure 200, which is the processing performed on or over the received substrate 201, in accordance with the accepted use of frontside (e.g., a positive z-direction). The backside is then opposite the frontside and is the side opposite the buildup direction (e.g., a negative z-direction).

As shown, insulative liner layer 211 laterally surrounds metal via 212 and is between metal via 212 and other components of transistor structure 200. Insulative liner layer 211 provides electrical isolation of metal via 212 from the other components of the transistor. Insulative liner layer 211 may be any suitable material such as silicon nitride (e.g., includes silicon and nitrogen), silicon oxide (e.g., includes silicon and oxygen), or other insulative material. Metal via 212 may be any suitable metal. In some embodiments, metal via 212 is or includes tungsten. However other metals may be deployed such as copper, aluminum, or others. As shown in the top-down view of FIG. 2B, transistor structure 200 may include metal via 212 and insulative liner layer 211 extending through or adjacent gate structure 205. However, metal via 212 and insulative liner layer 211 may be formed through or adjacent source structures 221, drain structures 222, or any other suitable component of transistor structure 200.

Returning to FIG. 1, processing continues at operation 102, where the frontside of the workpiece received at operation 102 is attached to a carrier, and a backside of the transistor structure is exposed. In some embodiments, the partially fabricated workpiece is mounted, by its frontside, to a carrier such as a carrier wafer, and the discussed bridge via and transistor semiconductor structure are exposed through the backside of the substrate of the workpiece. The workpiece may be mounted to the carrier using any suitable technique or techniques such as application of an adhesive film between the workpiece and carrier. The bridge via is then exposed using any suitable technique or techniques such as backside substrate removal processing including backside grind, backside etch, or the like to thin the substrate.

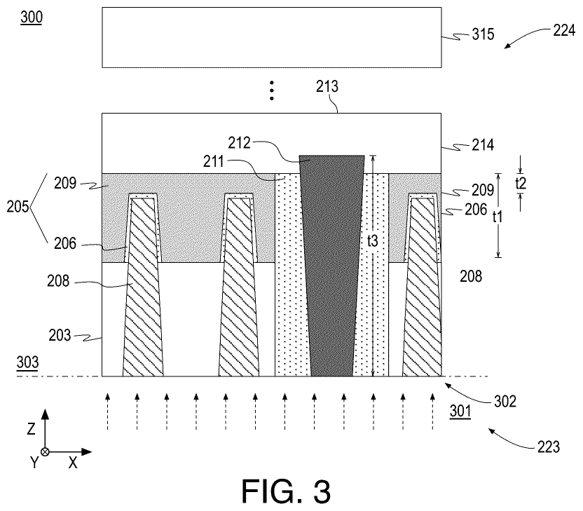

FIG. 3 illustrates a cross-sectional side view of a transistor structure 300 similar to transistor structure 200 after attachment of a carrier 315 to frontside 224 and material removal 301 of backside material 302 to expose semiconductor structures 208. As shown, carrier 315 is attached over frontside 224 of transistor structure 300. Carrier 315 may be attached over a metallization layer or level similar to metallization layer 217. For example, carrier 315 may be coupled to a passivation layer that is formed on or over a top metallization layer of transistor structure 300. In some embodiments, the carrier such as a carrier wafer is attached using an adhesive film between the workpiece and carrier 315, although other techniques may be used.

After attachment to carrier 315, material is removed via material removal 301 from backside 223 of transistor structure 300 to expose backsides of semiconductor structures 208, metal via 212, insulative liner layer 211, and insulative layer 203. Material removal 301 may be performed to remove material from backside 223 using any suitable technique or techniques such as chemical mechanical polishing (CMP) techniques. As shown, material removal 301 may provide a substantially planar backside surface 303 such that the backside surfaces of each of semiconductor structures 208, metal via 212, insulative liner layer 211, and insulative layer 203 are substantially coplanar (e.g., in the x-y plane).

Returning to FIG. 1, processing continues at operation 103, where an etch out of filler material is performed to etch backside material from the semiconductor structure (e.g., backside of the fin) and the insulative material laterally adjacent to the fin. For example, a portion of a backside of a subfin and a portion of the insulative material laterally adjacent to the subfin may be removed. Such etch treatment is selective to the subfin material and the laterally adjacent insulative material such that the subfin material and the laterally adjacent insulative material are etched while other structures such as the metal via and via liner are not substantially etched. The discussed etch out may be performed using any suitable technique or techniques such as selective plasma etch techniques. As discussed, these etch techniques reduce the thickness of the semiconductor structure and introduce trap charges into the semiconductor structure, which can disadvantageously cause Vt shift. For example, plasma etch of the filler materials and backside of the semiconductor structures bombards the remaining filler materials and semiconductor structure portions with charges. Furthermore, gate dielectric 206 and the work function metal of gate electrode 209 can introduce trap charges as well. Without the mitigation techniques discussed below, such introduction of trap charges can cause undesirable Vt shifts in the range of about 40 to 60 mV.

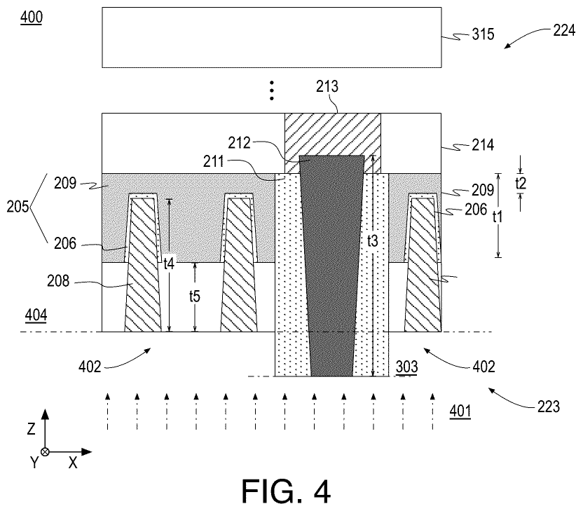

FIG. 4 illustrates a cross-sectional side view of a transistor structure 400 similar to transistor structure 300 after a selective etch 401 of portions 402 of semiconductor structures 208 and insulative layer 203. As discussed, selective etch 401 may be a plasma etch. In some embodiments, semiconductor structures 208 are or include silicon and insulative layer 203 is or includes silicon oxide while insulative liner layer 211 is or includes silicon nitride and metal via 212 is or includes tungsten. In some embodiments, selective etch 401 is a plasma etch that selectively etches silicon and silicon oxide while not substantially etching silicon nitride and tungsten.

As shown, selective etch 401 may provide a substantially planar backside surface 404 such that the backside surfaces of each of semiconductor structures 208 and insulative layer 203 are substantially coplanar (e.g., in the x-y plane). Also as shown, selective etch 401 may not substantially etch metal via 212 and insulative liner layer 211. For example, selective etch 401 may not substantially alter the previously discussed planar backside surface 303 such that the backside surfaces of each of metal via 212 and insulative liner layer 211 are substantially coplanar (e.g., in the x-y plane) at substantially planar backside surface 303.

As shown, in some embodiments, semiconductor structures 208 are etched back to a depth, vertical height, or thickness t4 (e.g., in the z-direction) that may be in the range of about 80 to 120 nm. In some embodiments, thickness t4 is in the range of 90 to 110 nm. In some embodiments, thickness t4 is in the range of 80 to 100 nm. Other thicknesses may be used. Furthermore, insulative layer 203 may be etched back to a depth, vertical height, or thickness t5 (e.g., in the z-direction) of about 30 to 70 nm. In some embodiments, thickness t5 is in the range of 40 to 60 nm. In some embodiments, thickness t5 is in the range of 30 to 50 nm. Other thicknesses may be used. In some embodiments, the portions of semiconductor structures 208 laterally adjacent to insulative layer 203 (e.g., a thickness of t5 of semiconductor structures 208) may be defined as a subfin portion of semiconductor structures 208. The upper portions of semiconductor structures 208 (e.g., a thickness of t4-t5 of semiconductor structures 208) may be characterized as an active fin portion of semiconductor structures 208.

Returning to FIG. 1, processing continues at operation 104, where a conformal insulative layer or passivation layer is formed or deposited on the backside surfaces of the exposed semiconductor structures, insulative layer, metal via and insulative liner layer. The conformal insulative layer or passivation layer may be deposited using any suitable technique or techniques such as chemical vapor deposition (CVD) inclusive of low pressure chemical vapor deposition (LPCVD). The conformal insulative layer may be any suitable insulative material deposited to any suitable thickness.

In some embodiments, the insulative layer formed at operation 104 is a silicon nitride layer (e.g., a layer including silicon and nitrogen) having a thickness of about 5 nm. In some embodiments, the insulative layer or passivation layer includes one or more of silicon, carbon, oxygen, and nitrogen. In some embodiments, the insulative layer or passivation layer is silicon nitride (e.g., includes silicon and nitrogen). In some embodiments, the insulative layer or passivation layer is aluminum oxide (e.g., includes aluminum and oxygen). In some embodiments, the insulative layer or passivation layer is silicon carbide (e.g., includes silicon and carbon). In some embodiments, the insulative layer or passivation layer is silicon oxynitride (e.g., includes silicon, oxygen, and nitrogen). In some embodiments, insulative layer or passivation layer is a silicon carbon oxynitride, SiCON (e.g., includes silicon, carbon, oxygen, and nitrogen). In some embodiments, insulative layer or passivation layer is SiCO (e.g., includes silicon, carbon, and oxygen). Other materials may be used.

As discussed, the insulative layer or passivation layer may be deposited to any suitable thickness such as a thickness in the range of 3 to 10 nm, a thickness of not more than 10 nm, a thickness of about 5 nm, or a thickness of not more than 5 nm. Other thicknesses may be used.

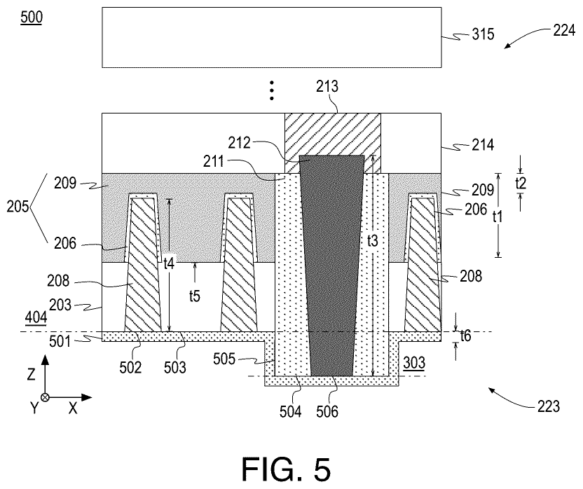

FIG. 5 illustrates a cross-sectional side view of a transistor structure 500 similar to transistor structure 400 after deposition of a conformal insulative layer 501. As discussed, conformal insulative layer 501 may be deposited using CVD, LPCVD, or other suitable deposition techniques. In some embodiments, conformal insulative layer 501 is conformal such that it has substantially the same thickness t6 on backside surfaces 502 of semiconductor structures 208, backside surface 503 of insulative layer 203, sidewall surface 505 of insulative liner layer 211, backside surface 504 of insulative liner layer 211, and backside surface 506 of metal via 212. As shown, conformal insulative layer 501 is formed on backside surfaces 502 of semiconductor structures 208 and backside surface 503 of insulative layer 203, which were formed at operation 103. Conformal insulative layer 501 is also formed on sidewall surface 505 of insulative liner layer 211, which was exposed at operation 103, and on backside surface 504 of insulative liner layer 211 and backside surface 506 of metal via 212, which were formed at operation 102.

Thickness t6 may be any suitable thickness. In some embodiments, thickness t6 is in the range of 3 to 10 nm. In some embodiments, thickness t6 is in the range of 4 to 6 nm. In some embodiments, thickness t6 is in the range of 3 to 5 nm. In some embodiments, thickness t6 is not more than 10 nm. In some embodiments, thickness t6 is not more than 5 nm. Other thicknesses may be used. Conformal insulative layer 501 may be any material discussed above such as SiN, SiON, SiC, AlO, SiCON, or SiCO.

Returning to FIG. 1, processing continues at operation 105, where an ozone/ultraviolet light (e.g., O₃/UV) treatment is performed to remove trap charges introduced at operation 103 from the semiconductor structure of the transistor. The ozone/UV treatment may be characterized as an ozone/UV cure, ozone/UV anneal, or the like. In some embodiments, the ozone/UV treatment applies a UV light (e.g., wavelengths in the range of 100 to 400 nm, with wavelengths in the range of 180 to 300 nm being particularly advantageous) in an ozone rich or pure ozone environment. In some embodiments, the ozone/UV treatment may be provided at an elevated temperature. The ozone/UV treatment applied to the backside of the passivation layer removes trap charges from the semiconductor structure to the passivation layer for reduced trap charges and mitigation or elimination of Vt shift.

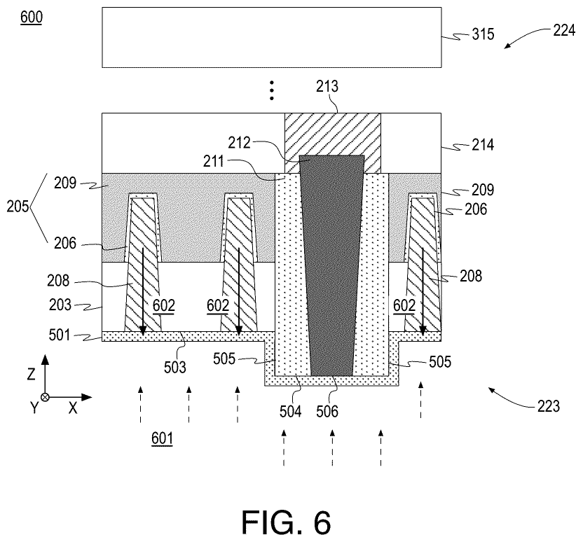

FIG. 6 illustrates a cross-sectional side view of a transistor structure 600 similar to transistor structure 500 during an ozone/UV treatment 601 to remove trap charges from semiconductor structures 208 and/or other components of transistor structure 600. In some embodiments, ozone/UV treatment 601 applies UV light in an ozone rich or pure ozone environment to remove trap charges as shown with respect to trap charges removal 602. Although illustrated with respect to trap charges removal 602 using downward arrows for the sake of clarity of presentation, the trap charges may be mitigated or resolved using any suitable mechanism such as removal, recovery, migration, resolution of lattice defects and/or bonds in semiconductor structures 208, and others. In some embodiments, the ozone/UV treatment may be provided at an elevated temperature. As discussed, such trap charges removal 602 mitigates or eliminates Vt shift such as in-line to end-of-line Vt shift.

Returning to FIG. 1, processing continues at operation 106, where an insulative fill material is deposited and planarized. The insulative fill material may be deposited using any suitable technique or techniques such as CVD, and polarized using any suitable technique or techniques such as CMP processing. For example, the insulative fill material may be bulk deposited and then polished back to expose back surfaces of the bridge via and bridge via insulator liner while covering the previously exposed semiconductor structures such that the conformal insulative layer formed at operation 104 is between the back surfaces of the semiconductor structures and the insulative fill material. The insulative fill material may be any insulator material such as a silicon oxide.

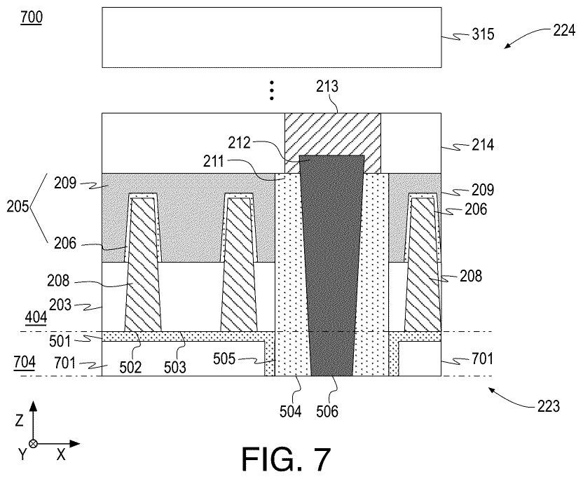

FIG. 7 illustrates a cross-sectional side view of a transistor structure 700 similar to transistor structure 600 after formation of insulative layer 701. As shown, insulative layer 701 is formed in the recess defined by the etch out illustrated in FIG. 4. Insulative layer 701 may be any suitable material such as silicon dioxide and may be formed by bulk deposition and planarization techniques to provide a substantially planar backside surface 704. As shown, transistor structure 700 includes conformal insulative layer 501 (e.g., a first insulative layer) on backside surfaces 502 (e.g., backside) of the semiconductor structures 208, and insulative layer 701 (e.g., a second insulative layer or insulative fill layer) on conformal insulative layer 501. In some embodiments, conformal insulative layer 501 and insulative layer 701 are different materials, with the material of conformal insulative layer 501 facilitating passivation and removal of trap charges while insulative layer 701 provides a bulk or fill material. In some embodiments, conformal insulative layer 501 is one of silicon nitride, silicon oxynitride, silicon carbide, aluminum oxide, silicon-carbon oxynitrides, or silicon oxycarbide.

Returning to FIG. 1, processing continues at operation 107, where any number of levels of backside metallization are formed opposite the frontside metallization layers with respect to the transistor or device layer. As discussed, a partially fabricated workpiece is mounted, by its frontside, to a carrier such as a carrier wafer, and the bridge via is exposed through the backside of the substrate of the workpiece. The backside metallization layers are then fabricated over the exposed bridge via (and opposite the transistor layer with respect to the frontside metallization layers). In some embodiments, one of the backside metallization layers such that a metallization feature of one of the backside metallization layers contacts the bridge via. The backside metallization layers may be formed using any suitable technique or techniques such as dual damascene techniques, single damascene techniques, subtractive metallization patterning techniques, or the like. For example, power-delivery may be provided by the backside metallization layers to the bridge via to power the transistors of the device layer. Although discussed with respect to power delivery, interconnectivity, signal routing, a ground plane, or other functionalities may be provided by the backside metallization layers.

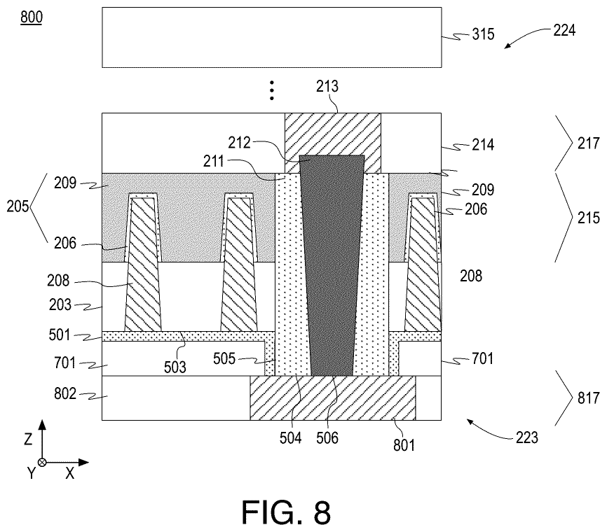

FIG. 8 illustrates a cross-sectional side view of a transistor structure 800 similar to transistor structure 700 after formation of metallization layer 817 over backside 223 of transistor structure 800. Metallization layer 817 may include any number of metallization features such as metallization feature 801 (e.g., a metal line, metal via, metal contact, etc.) embedded in an insulative material 802. As discussed, metallization layer 817 and any additional layers extending below metallization layer 817 may be formed using any suitable technique or techniques. Metallization layer 817 may be one of any number of metallization layers such as two to five such layers that include metal lines and metal vias interconnecting the metal lines. As shown, metal via 212 (e.g., a bridge via) contacts metallization feature 801 such that metal via 212 extends from metallization layer 217 to metallization layer 217 and thereby bridges device layer 215 from frontside 224 of transistor structure 800 to backside 223 of transistor structure 800.

Returning to FIG. 1, processing continues at operation 108, where the carrier attached at operation 102 may be removed and at operation 109, where continued processing is performed as is known in the art to dice, package, and output an integrated circuit (IC) die, package, or device including the discussed features. At operation, the carrier may be removed using any suitable technique or techniques such as delamination, UV curing, or the like. At operation 109, the continued processing may include dicing, packaging, assembly, and so on. The resultant device (e.g., IC die, IC package, IC assembly, etc.) may then be implemented in any suitable form factor device such as a laptop, a netbook, a notebook, an ultrabook, a smartphone, a tablet, a personal digital assistant, an ultra-mobile PC, a mobile phone, a desktop computer, a server, a printer, a scanner, a monitor, a set-top box, an entertainment control unit, a digital camera, a portable music player, a digital video recorder, or the like.

FIG. 9A illustrates a cross-sectional side view of a transistor structure 900 similar to transistor structure 800 after removal of carrier 315 via delamination, UV curing, or the like. With reference to FIGS. 9A and 9B, transistor structure 900 includes one or more transistors such as a transistor 901. Transistor 901 includes one or more semiconductor structures such as semiconductor structure 208 extending between source structure 221 and drain structure 222, and gate structure 205 over channel region 225 of semiconductor structure 208. In some embodiments, semiconductor structure 208 may be characterized as a semiconductor material, source structure 221 and drain structure 222 may be characterized as a source and drain, and gate structure 205 may be characterized as a gate. As discussed, gate structure 205 includes gate dielectric 206 and gate electrode 209, which may include a work function metal on gate dielectric 206 and a bulk metal on the work function metal.

Also as shown, transistor structure 900 includes metal via 212 (e.g., a bridge via, a power via, a deep power via, or, simply, a via) extending from metallization layer 217 (e.g., a frontside metallization or a frontside metallization layer) that is over transistor 901 to metallization layer 817 (e.g., a backside metallization or a backside metallization layer) that is below transistor 901. For example, metal via 212 spans device layer 215 and contacts metallization feature 213 of metallization layer 217 and contacts metallization feature 801 of metallization layer 817. Conformal insulative layer 501 (e.g., a first insulative layer) is on backside surfaces 502 (e.g., a backside) of semiconductor structure 208. As discussed, conformal insulative layer 501 provides passivation and trap charge removal. Conformal insulative layer 501 may be characterized as a passivation layer, an insulative layer, or an insulative material. Furthermore, insulative material 802 such as an insulative fill layer (e.g., a second insulative layer) is on the first insulative layers. Insulative material 802 may provide a fill material that is below semiconductor structure 208 and laterally adjacent a portion of metal via 212 and a portion of insulative liner layer 211.

Conformal insulative layer 501 and insulative material 802 may be any materials and have any characteristics discussed above. In some embodiments, conformal insulative layer 501 includes one or more of silicon, carbon, oxygen, and nitrogen. In some embodiments, conformal insulative layer 501 includes silicon and nitrogen (e.g., is pure or substantially pure silicon nitride) or aluminum and oxygen (e.g., is pure or substantially pure aluminum oxide). In some embodiments, conformal insulative layer 501 includes silicon and nitrogen (e.g., is pure or substantially pure silicon nitride) and insulative material 802 includes silicon and oxygen (e.g., is pure or substantially pure silicon dioxide). In some embodiments, conformal insulative layer 501 has a thickness of not more than 10 nm. In some embodiments, conformal insulative layer 501 has a thickness of not more than 5 nm. In some embodiments, conformal insulative layer 501 has a thickness in the range of 1 to 5 nm.

The other components of transistor structure 900 may also be any materials and have any characteristics discussed above. In some embodiments, semiconductor structure 208 has a thickness t4 between backside 223 of semiconductor structure 208 and frontside 224 of semiconductor structure 208 of not more than 100 nm. As shown, transistor structure 900 further includes insulative liner layer 211 (e.g., an insulative liner) adjacent metal via 212 such that a portion 905 of conformal insulative layer 501 is on sidewall surface 505 of insulative liner layer 211. In some embodiments, a bottom surface 906 of insulative material 802 is substantially coplanar with backside surface 506 of meta via 212 and backside surface 504 of insulative liner layer 211.

Furthermore, gate structure 205 is on a first portion 911 of semiconductor structure 208, insulative layer 203 (e.g., a third insulative layer) is on a second portion 912 of semiconductor structure 208, and gate structure 205 is on insulative layer 203 at an interface 913 therebetween. In some embodiments, a bottom surface 914 of insulative layer 203 is substantially coplanar with backside surface 502 of semiconductor structure 208. In some embodiments, conformal insulative layer 501 is on bottom surface 914 of insulative layer 203. In some embodiments, metallization feature 801 metallization layer 817 is a power delivery metallization feature (e.g., backside power delivery feature) in contact with metal via 212.

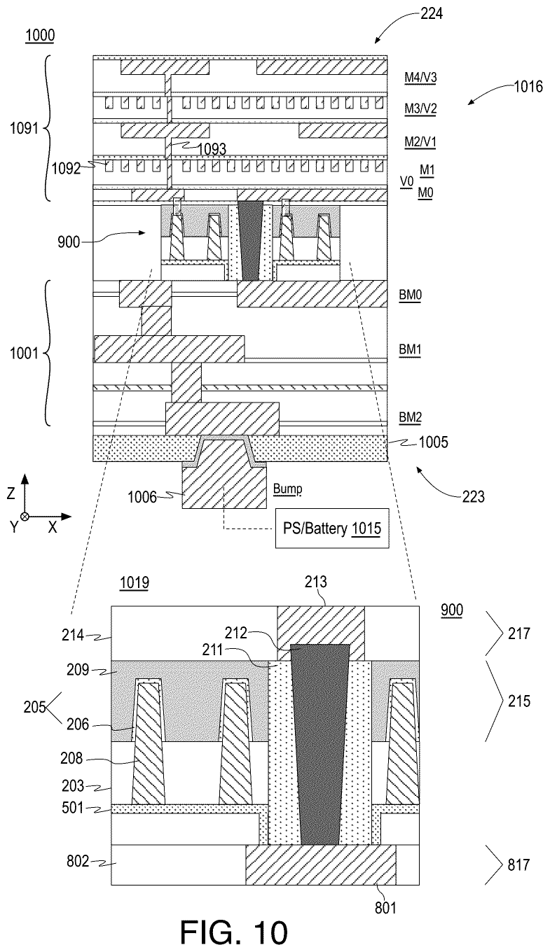

FIG. 10 illustrates a cross-sectional side view of an integrated circuit device structure 1000 similar to transistor structure 900 after incorporation of transistor structure 900 into an integrated circuit die 1016, arranged in accordance with some embodiments of the disclosure. In FIG. 10, transistor structure 900 is shown in expanded view 1019. As shown, any number of frontside metallization layers 1091, including metallization layer 217, may be formed over device layer 215. For example, interconnectivity, signal routing, optional power-delivery, and the like may be provided by frontside metallization layers 1091. As used herein, the term metallization layer indicates metal interconnections or wires that provide electrical routing. Adjacent metallization layers, such as metallization interconnects 1092, are interconnected by vias, such as vias 1093, that may be characterized as part of the metallization layers or between the metallization layers. As shown, in some embodiments, frontside metallization layers 1091 are formed over and immediately adjacent transistor structure 900. In the illustrated example, frontside metallization layers 1091 include M0, V0, M1, M2/V1, M3/V2, and M4/V3. However, frontside metallization layers 1091 may include any number of metallization layers such as six, eight, or more metallization layers.

Furthermore, backside metallization layers 1001, including metallization layer 817, may be formed under device layer 215. For example, power-deliver, optional additional interconnectivity, and routing to outside devices (not shown) may be provided by backside metallization layers 1001. As shown, in some embodiments, backside metallization layers 1001 are formed over and immediately adjacent transistor structure 900. In the illustrated example, backside metallization layers 1001 include BM0, BM1, and BM2 with intervening via layers. However, backside metallization layers 1001 are may include any number of metallization layers such as three, four, or more metallization layers. In the illustrated example, package level interconnects 1006 are provided on or under backside 223 as bumps over a passivation layer 1005. However, package level interconnects 1006 may be provided using any suitable interconnect structures such as bond pads, solder bumps, etc. In some embodiments, integrated circuit die 1016 includes any transistor structure discussed herein, and integrated circuit die 1016 is coupled to a power supply/battery 1015, which may be any suitable power supply device or component. In addition or in the alterative, integrated circuit die 1016 may couple to other devices such as a display, a peripheral device, or the like. For example, integrated circuit die 1016 may couple to any component discussed herein below.

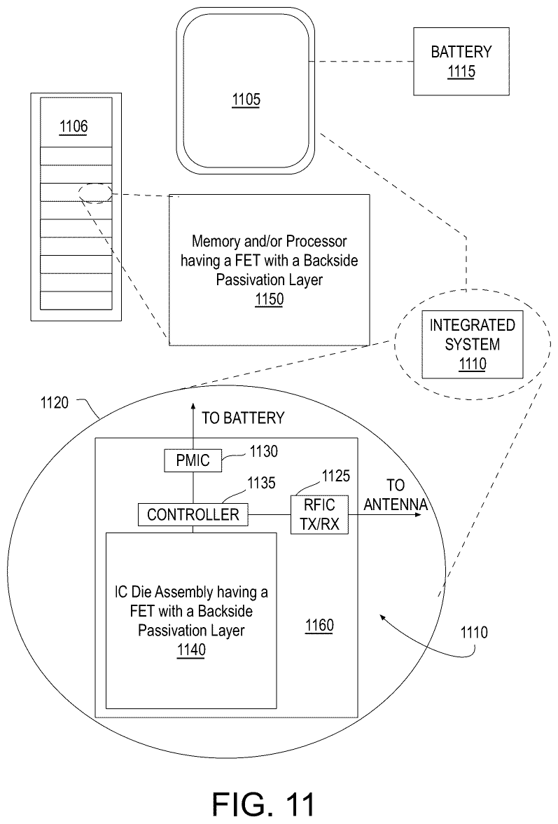

FIG. 11 illustrates exemplary systems employing transistor structures having a field effect transistor with a backside passivation layer, in accordance with some embodiments. The system may be a mobile computing platform 1105 and/or a data server machine 1106, for example. Either may employ a monolithic IC die, for example, having a field effect transistor with a backside passivation layer as described elsewhere herein. Server machine 1106 may be any commercial server, for example including any number of high-performance computing platforms disposed within a rack and networked together for electronic data processing, which in the exemplary embodiment includes an IC die assembly 1150 with a field effect transistor with a backside passivation layer used to remove trapped charges as described elsewhere herein. Mobile computing platform 1105 may be any portable device configured for each of electronic data display, electronic data processing, wireless electronic data transmission, or the like. For example, mobile computing platform 1105 may be any of a tablet, a smart phone, a laptop computer, etc., and may include a display screen (e.g., a capacitive, inductive, resistive, or optical touchscreen), a chip-level or package-level integrated system 1110, and a battery/power supply 1115. Although illustrated with respect to mobile computing platform 1105, in other examples, chip-level or package-level integrated system 1110 and a battery/power supply 1115 may be implemented in a desktop computing platform, an automotive computing platform, an internet of things platform, or the like. As discussed below, in some examples, the disclosed systems may include a sub-system 1160 such as a system on a chip (SOC) or an integrated system of multiple ICs, which is illustrated with respect to mobile computing platform 1105.

Whether disposed within integrated system 1110 illustrated in expanded view 1120 or as a stand-alone packaged device within data server machine 1106, sub-system 1160 may include memory circuitry and/or processor circuitry 1140 (e.g., RAM, a microprocessor, a multi-core microprocessor, graphics processor, etc.), a power management integrated circuit (PMIC) 1130, a controller 1135, and a radio frequency integrated circuit (RFIC) 1125 (e.g., including a wideband RF transmitter and/or receiver (TX/RX)). As shown, one or more IC dice, such as memory circuitry and/or processor circuitry 1140 may be assembled and implemented such that one or more have a backside passivation layer used to remove trapped charges as described herein. In some embodiments, RFIC 1125 includes a digital baseband and an analog front end module further comprising a power amplifier on a transmit path and a low noise amplifier on a receive path). Functionally, PMIC 1130 may perform battery power regulation, DC-to-DC conversion, etc., and so has an input coupled to battery/power supply 1115, and an output providing a current supply to other functional modules. As further illustrated in FIG. 11, in the exemplary embodiment, RFIC 1125 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Memory circuitry and/or processor circuitry 1140 may provide memory functionality for sub-system 1160, high level control, data processing and the like for sub-system 1160. In alternative implementations, each of the SOC modules may be integrated onto separate ICs coupled to a package substrate, interposer, or board.

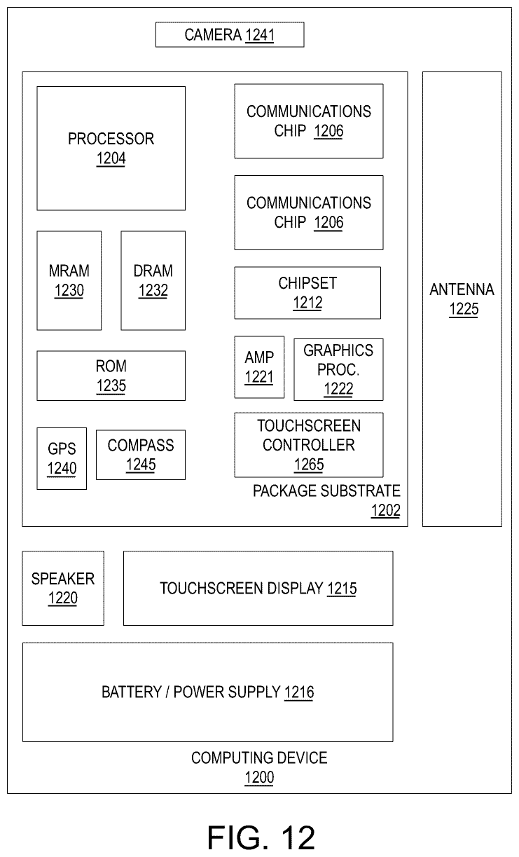

FIG. 12 is a functional block diagram of an electronic computing device 1200, in accordance with some embodiments. For example, device 1200 may, via any suitable component therein, implement a field effect transistor and a backside passivation layer used to remove trapped charges as discussed herein. For example, one or more IC dies of electronic computing device 1200 may deploy a field effect transistor and a backside passivation layer used to remove trapped charges from a semiconductor structure of the field effect transistor. Device 1200 further includes a motherboard or package substrate 1202 hosting a number of components, such as, but not limited to, a processor 1204 (e.g., an applications processor). Processor 1204 may be physically and/or electrically coupled to package substrate 1202. In some examples, processor 1204 is within an IC assembly. In general, the term “processor” or “microprocessor” may refer to any device or portion of a device that processes electronic data from registers and/or memory to transform that electronic data into other electronic data that may be further stored in registers and/or memory.

In various examples, one or more communication chips 1206 may also be physically and/or electrically coupled to the package substrate 1202. In further implementations, communication chips 1206 may be part of processor 1204. Depending on its applications, computing device 1200 may include other components that may or may not be physically and electrically coupled to package substrate 1202. These other components include, but are not limited to, volatile memory (e.g., DRAM 1232), non-volatile memory (e.g., ROM 1235), flash memory (e.g., NAND or NOR), magnetic memory (MRAM 1230), a graphics processor 1222, a digital signal processor, a crypto processor, a chipset 1212, an antenna 1225, touchscreen display 1215, touchscreen controller 1265, battery/power supply 1216, audio codec, video codec, power amplifier 1221, global positioning system (GPS) device 1240, compass 1245, accelerometer, gyroscope, speaker 1220, camera 1241, and mass storage device (such as hard disk drive, solid-state drive (SSD), compact disk (CD), digital versatile disk (DVD), and so forth, or the like.

Communication chips 1206 may enable wireless communications for the transfer of data to and from the computing device 1200. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 1206 may implement any of a number of wireless standards or protocols, including, but not limited to, those described elsewhere herein. As discussed, computing device 1200 may include a plurality of communication chips 1206. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others. Battery/power supply 1216 may include any suitable power supply circuitry and, optionally, a battery source to provide power to components of electronic computing device 1200.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described but can be practiced with modification and alteration without departing from the scope of the appended claims. For example, the above embodiments may include specific combinations of features as further provided below.

The following pertains to exemplary embodiments.

In one or more first embodiments, an apparatus comprises a transistor comprising a semiconductor structure extending between a source structure and a drain structure, and a gate structure over a channel region of the semiconductor structure, a via extending from a frontside metallization over the transistor to a backside metallization below the transistor, a first insulative layer on a backside of the semiconductor structure, and a second insulative layer on the first insulative layer.

In one or more second embodiments, further to the first embodiments, the first insulative layer comprises one or more of silicon, carbon, oxygen, and nitrogen.

In one or more third embodiments, further to the first or second embodiments, the first insulative layer comprises silicon and nitrogen or aluminum and oxygen.

In one or more fourth embodiments, further to the first through third embodiments, the first insulative layer comprises silicon and nitrogen and the second insulative layer comprises silicon and oxygen, such that the first insulative layer has a thickness of not more than 10 nm.

In one or more fifth embodiments, further to the first through fourth embodiments, the semiconductor structure has a thickness between the backside of the semiconductor structure and a frontside of the semiconductor structure of not more than 100 nm.

In one or more sixth embodiments, further to the first through fifth embodiments, the apparatus further comprises an insulative liner adjacent the via, wherein a portion of the first insulative layer is on a sidewall of the insulative liner.

In one or more seventh embodiments, further to the first through sixth embodiments, a bottom surface of the second insulative layer is substantially coplanar with a bottom surface of the via.

In one or more eighth embodiments, further to the first through seventh embodiments, the gate structure is on a first portion of the semiconductor structure, a third insulative layer is on a second portion of the semiconductor structure, and the gate structure is on the third insulative layer, and a bottom surface of the third insulative layer is substantially coplanar with a bottom surface of the semiconductor structure and the first insulative layer is on the bottom surface of the third insulative layer.

In one or more ninth embodiments, further to the first through eighth embodiments, the backside metallization comprises a power delivery metallization feature in contact with the via.

In one or more tenth embodiments, a system comprises an IC die including an apparatus according to any of the apparatuses of the first through ninth embodiments, and a power supply and/or display coupled to the IC die.

In one or more eleventh embodiments, a system comprises an integrated circuit (IC) die comprising a transistor comprising a semiconductor structure extending between a source and a drain, and a gate on a frontside of the semiconductor structure, a bridge via extending from a frontside metal over the transistor to a backside metal below the transistor, a conformal insulative layer on a backside of the semiconductor structure, and an insulative fill layer on the conformal insulative layer, and a power supply and/or display coupled to the IC die.

In one or more twelfth embodiments, further to the eleventh embodiments, the conformal insulative layer comprises silicon and nitrogen and the insulative fill layer comprises silicon and oxygen, such that the conformal insulative layer has a thickness of not more than 10 nm.

In one or more thirteenth embodiments, further to the eleventh or twelfth embodiments, the semiconductor structure has a thickness between the frontside of the semiconductor structure and the backside of the semiconductor structure of not more than 100 nm.

In one or more fourteenth embodiments, further to the eleventh through thirteenth embodiments, the system further comprises an insulative liner adjacent the bridge via, wherein a portion of the conformal insulative layer is on a sidewall of the insulative liner, and a bottom surface of the insulative fill layer is substantially coplanar with a bottom surface of the bridge via.

In one or more fifteenth embodiments, further to the eleventh through fourteenth embodiments, the gate is on a first portion of the semiconductor structure, a second insulative fill layer is on a second portion of the semiconductor structure, and the gate is on the second insulative fill layer, and a bottom surface of the second insulative fill layer is substantially coplanar with a bottom surface of the semiconductor structure and the conformal insulative layer is on the bottom surface of the second insulative fill layer.

In one or more sixteenth embodiments, a method comprises exposing a backside of a semiconductor structure, wherein the semiconductor structure extends between a source structure and a drain structure, and a gate structure is couple to the semiconductor structure, etching at least a portion of the semiconductor structure via the exposed backside of the semiconductor structure to form a surface of the semiconductor structure, forming a first insulative layer on the surface of the semiconductor structure, performing an ozone and ultraviolet anneal of the first insulative layer, and forming a second insulative layer over the first insulative layer.

In one or more seventeenth embodiments, further to the sixteenth embodiments, the first insulative layer comprises one or more of silicon, carbon, oxygen, and nitrogen.

In one or more eighteenth embodiments, further to the sixteenth or seventeenth embodiments, the first insulative layer comprises silicon and nitrogen and the second insulative layer comprises silicon and oxygen, such that the first insulative layer has a thickness of not more than 10 nm.

In one or more nineteenth embodiments, further to the sixteenth through eighteenth embodiments, the first insulative layer has a thickness of not more than 5 nm.

In one or more twentieth embodiments, further to the sixteenth through nineteenth embodiments, a via extends from a frontside metallization over the semiconductor structure to a backside surface of the via, and etching at least the portion of the semiconductor structure provides an etch back of the semiconductor structure such that the backside surface of the via is below the surface of the semiconductor structure.

In one or more twenty-first embodiments, further to the sixteenth through twentieth embodiments, forming the first insulative layer on the surface of the semiconductor structure further forms the first insulative layer on a sidewall of an insulative liner adjacent the via.

It will be recognized that the invention is not limited to the embodiments so described but can be practiced with modification and alteration without departing from the scope of the appended claims. For example, the above embodiments may include specific combination of features. However, the above embodiments are not limited in this regard, and, in various implementations, the above embodiments may include the undertaking only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

What is claimed is:

1. An apparatus, comprising:
a transistor comprising a semiconductor structure extending between a source structure and a drain structure, and a gate structure over a channel region of the semiconductor structure;
a via extending from a frontside metallization over the transistor to a backside metallization below the transistor;
a first insulative layer on a backside of the semiconductor structure; and
a second insulative layer on the first insulative layer.

2. The apparatus of claim 1, wherein the first insulative layer comprises one or more of silicon, carbon, oxygen, and nitrogen.

3. The apparatus of claim 1, wherein the first insulative layer comprises silicon and nitrogen or aluminum and oxygen.

4. The apparatus of claim 1, wherein the first insulative layer comprises silicon and nitrogen and the second insulative layer comprises silicon and oxygen, wherein the first insulative layer has a thickness of not more than 10 nm.

5. The apparatus of claim 4, wherein the semiconductor structure has a thickness between the backside of the semiconductor structure and a frontside of the semiconductor structure of not more than 100 nm.

6. The apparatus of claim 1, further comprising an insulative liner adjacent the via, wherein a portion of the first insulative layer is on a sidewall of the insulative liner.

7. The apparatus of claim 6, wherein a bottom surface of the second insulative layer is substantially coplanar with a bottom surface of the via.

8. The apparatus of claim 1, wherein the gate structure is on a first portion of the semiconductor structure, a third insulative layer is on a second portion of the semiconductor structure, and the gate structure is on the third insulative layer, and wherein a bottom surface of the third insulative layer is substantially coplanar with a bottom surface of the semiconductor structure and the first insulative layer is on the bottom surface of the third insulative layer.

9. The apparatus of claim 1, wherein the backside metallization comprises a power delivery metallization feature in contact with the via.

10. A system, comprising:
an integrated circuit (IC) die comprising:
a transistor comprising a semiconductor structure extending between a source and a drain, and a gate on a frontside of the semiconductor structure;
a bridge via extending from a frontside metal over the transistor to a backside metal below the transistor;
a conformal insulative layer on a backside of the semiconductor structure; and
an insulative fill layer on the conformal insulative layer; and
a power supply coupled to the IC die.

11. The system of claim 10, wherein the conformal insulative layer comprises silicon and nitrogen and the insulative fill layer comprises silicon and oxygen, wherein the conformal insulative layer has a thickness of not more than 10 nm.

12. The system of claim 11, wherein the semiconductor structure has a thickness between the frontside of the semiconductor structure and the backside of the semiconductor structure of not more than 100 nm.

13. The system of claim 10, further comprising an insulative liner adjacent the bridge via, wherein a portion of the conformal insulative layer is on a sidewall of the insulative liner, and a bottom surface of the insulative fill layer is substantially coplanar with a bottom surface of the bridge via.

14. The system of claim 10, wherein the gate is on a first portion of the semiconductor structure, a second insulative fill layer is on a second portion of the semiconductor structure, and the gate is on the second insulative fill layer, and wherein a bottom surface of the second insulative fill layer is substantially coplanar with a bottom surface of the semiconductor structure and the conformal insulative layer is on the bottom surface of the second insulative fill layer.

15. A method, comprising:
exposing a backside of a semiconductor structure, wherein the semiconductor structure extends between a source structure and a drain structure, and a gate structure is couple to the semiconductor structure;
etching at least a portion of the semiconductor structure via the exposed backside of the semiconductor structure to form a surface of the semiconductor structure;
forming a first insulative layer on the surface of the semiconductor structure;
performing an ozone and ultraviolet anneal of the first insulative layer; and
forming a second insulative layer over the first insulative layer.

16. The method of claim 15, wherein the first insulative layer comprises one or more of silicon, carbon, oxygen, and nitrogen.

17. The method of claim 15, wherein the first insulative layer comprises silicon and nitrogen and the second insulative layer comprises silicon and oxygen, wherein the first insulative layer has a thickness of not more than 10 nm.

18. The method of claim 17, wherein the first insulative layer has a thickness of not more than 5 nm.

19. The method of claim 15, wherein a via extends from a frontside metallization over the semiconductor structure to a backside surface of the via, and wherein etching at least the portion of the semiconductor structure provides an etch back of the semiconductor structure such that the backside surface of the via is below the surface of the semiconductor structure.

20. The method of claim 19, wherein forming the first insulative layer on the surface of the semiconductor structure further forms the first insulative layer on a sidewall of an insulative liner adjacent the via.
